(19) United States
(12) Patent Application Publication
(10) Pub. No.: US 2025/0088127 A1
(43) Pub. Date: Mar. 13, 2025

(54) MOTOR CONTROL DEVICE

(71) Applicant: LG INNOTEK CO., LTD., Seoul (KR)

(72) Inventor: Won Kyu KIM, Seoul (KR)

(21) Appl. No.: 18/726,694

(22) PCT Filed: Jan. 5, 2023
(86) PCT No.: PCT/KR2023/000215

§ 371 Date: Jul. 3, 2024

(30) Foreign Application Priority Data
Jan. 5, 2022 (KR) 10-2022-0001749

(51) Int. Cl. H02P 7/28; H02P 6/04; H02P 6/16; H02P 6/26

(52) U.S. Cl. CPC H02P 7/28; H02P 6/04; H02P 6/16; H02P 6/26; H02P 2205/01

(57) ABSTRACT

A motor control device, according to an embodiment of the present invention, comprises: a switching unit including a first switch unit and a second switch unit; a first resistor connected to an output unit of the switching unit; and a control unit controlling a motor connected with the switching unit, wherein the second switch unit includes a plurality of unit switches and the control unit determines and controls the type of the motor by using at least one switch from among the plurality of unit switches and a current flowing through the first resistor.

### TECHNICAL FIELD

The present invention relates to a motor control device, and more particularly to a motor control device that is dually adaptable to a plurality of types of motors.

### BACKGROUND ARTS

A direct current motor (DC motor) is a motor that rotates using direct current power, and the direction of rotation varies depending on the direction of the current. A BLDC motor (Brush-Less Direct Current motor) is a motor that rotates using three-phase AC power, and the direction of rotation varies depending on the order of the three-phase input.

When it is necessary to selectively use a DC motor or a BLDC motor depending on the situation or need, the control method varies depending on whether the motor to which the controller controlling the motor is connected is a DC motor or a BLDC motor, so a technology for detecting the type of motor and a technology for determining the direction of rotation of the motor are required.

### DETAILED DESCRIPTION OF INVENTION

### Technical Subject

The technical subject that the present invention seeks to solve is to provide a motor control device that can be dually used with a plurality of different types of motors.

### Technical Solution

In one aspect of the present invention, there may be provided a motor control device, comprising: a switching unit including a first switch unit and a second switch unit; a first resistor connected to an output unit of the switching unit; and a control unit controlling a motor connected with the switching unit, wherein the second switch unit includes a plurality of unit switches and the control unit determines and controls the type of the motor by using at least one switch from among the plurality of unit switches and a current flowing through the first resistor.

Preferably, but not necessarily, the motor may include at least one of a DC motor and a BLDC motor.

Preferably, but not necessarily, the switching unit may include: a first to third upper switch; and a first to third lower switch, each connected in series with the upper switch; wherein the control unit is capable of turning on the second upper switch, the first lower switch, and the third lower switch, and detecting a type of the motor by means of a first current flowing in the first lower switch, a second current flowing in the third lower switch, and a third current flowing in the first resistor.

Preferably, but not necessarily, the control unit may determine that the motor is a BLDC motor if, when the first current, the second current, and the third current are above a threshold value, a position measurement value received from a position measurement sensor that measures the position of the motor is within a normal range.

Preferably, but not necessarily, the control unit may determine that the position measurement value is out of the normal range if the position measurement sensor is faulty.

Preferably, but not necessarily, the controller may determine that the motor is a DC motor if the first current, the second current, and the third current do not flow, and the position measurement value received from the position measurement sensor that measures the position of the motor is below a first value.

Preferably, but not necessarily, the control unit may determine that the power is faulty, if at least one of the first current, the second current, and the third current is below the threshold, but at least one of the first current, the second current, and the third current flows, and the position measurement value received from the position measurement sensor is greater than the first value.

Preferably, but not necessarily, the control unit may determine that the DC motor rotates in a first direction when the first upper switch and the third lower switch are turned on, and the third current and the second current remain above a threshold value for a threshold time, and determine that the DC motor rotates in a second direction when the third upper switch and the first lower switch are turned on, and the third current and the first current remain above a threshold value for a threshold time.

Preferably, but not necessarily, the control unit may include: a first amplifier for detecting a voltage difference across both sides of the first lower switch; a second amplifier for detecting a voltage difference across both sides of the third lower switch; and a third amplifier for detecting a voltage difference across both sides of the first resistor.

Preferably, but not necessarily, the control unit may control the DC motor by complementarily energizing the first and third upper switches and the first and third lower switches, if the motor is a DC motor, and may control the BLDC motor by complementarily energizing the first and third upper switches and the first and third lower switches, if the motor is a BLDC motor.

Preferably, but not necessarily, In another general aspect of the present invention, there may be provided a motor control device, comprising: a first to third unit switch; a fourth to sixth unit switch connected in series with each of the first to third unit switches; a first resistor connected with an output end of the fourth to sixth unit switch; a gate driver connected with both ends of the fourth unit switch and with both ends of the sixth unit switch; and a control unit connected with the gate driver, wherein both ends of the first resistor are connected with the gate driver.

Preferably, but not necessarily, the control unit may control a first DC motor or a second DC motor connected to the unit switches of at least some of the first to sixth unit switches, wherein the first DC motor may be a DC motor or a single-phase motor, and the second DC motor may be a BLDC motor or a three-phase motor.

### Advantageous Effects

According to embodiments of the present invention, it is possible to configure a controller for both DC motors and BLDC motors. In addition, a platform controller with optimized shunt resistance can be implemented, and it is possible to distinguish options and control operation of each type of motor without distinguishing hardware. Furthermore, it is possible to detect the current and direction of a DC motor without interfering with the operation of a BLDC motor.

### BRIEF DESCRIPTION OF DRAWINGS

FIG. 1 is a block diagram of a motor control device according to one embodiment of the present invention.

FIGS. 2 and 3 are block diagrams of a motor control device according to a comparative example of the present invention.

FIGS. 4 to 6 are block diagrams of a motor control device according to an embodiment of the present invention.

FIGS. 7 to 12 are drawings to illustrate a motor type detection and rotation direction detection process of a motor control device according to an embodiment of the present invention.

FIG. 13 is a block diagram of a motor control device according to an embodiment of the present invention.

### BEST MODE

Hereinafter, exemplary embodiments of the present invention will be described in detail with reference to the accompanying drawings.

However, it should be noted that the technical ideas of the present invention should not be construed as limited to some of the explained exemplary embodiments but may be embodied in mutually different various shapes, and one or more elements may be selectively coupled or substituted among exemplary embodiments as long as within the scope of technical concept of the present invention.

Furthermore, terms (including technical and scientific terms) used in the embodiments of the present invention, unless expressly specifically defined and described, are to be interpreted in the sense in which they would be understood by a person of ordinary skill in the art to which the present invention belongs, and commonly used terms, such as dictionary-defined terms, are to be interpreted in light of their contextual meaning in the relevant art.

Furthermore, the terms used in the embodiments of the invention are intended to describe the embodiments and are not intended to limit the invention.

In this specification, the singular may include the plural unless the context otherwise requires, and references to “at least one (or more) of A and (or) B and C” may include one or more of any combination of A, B, and C that may be assembled.

In addition, the terms first, second, A, B, (a), (b), and the like may be used to describe components of embodiments of the invention. Such terms are intended only to distinguish one component from another, and are not intended to limit the nature or sequence or order of such components by such terms.

Furthermore, when a component is described as “connected,” “coupled,” or “attached” to another component, it can include cases where the component is “connected,” “coupled,” or “attached” to the other component directly, as well as cases where the component is “connected,” “coupled,” or “attached” to another component that is between the component and the other component.

Furthermore, when described as being formed or disposed “above” or “below” each component, “above” or “below” includes not only when two components are in direct contact with each other, but also when one or more other components are formed or disposed between the two components. Furthermore, when expressed as “above” or “below”, it may include the meaning of upward as well as downward with respect to a single component.

Variations according to the present embodiments may include some configurations of each embodiment together with some configurations of other embodiments, i.e., a variation may include one embodiment of the various embodiments but omit some configurations and include some configurations of the corresponding other embodiments. Alternatively, the opposite may be true. The features, structures, effects, etc. described in the embodiments are included in at least one embodiment and are not necessarily limited to any one embodiment. Furthermore, the features, structures, effects, etc. exemplified in each embodiment may be combined or modified in other embodiments by one having ordinary knowledge in the field to which the embodiments belong. Accordingly, such combinations and modifications should be construed as being within the scope of the embodiments.

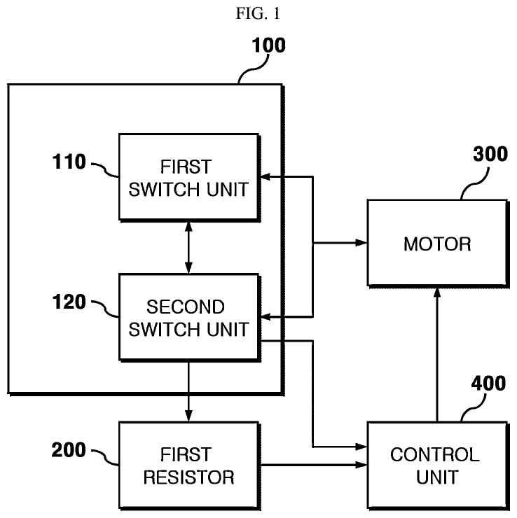

FIG. 1 is a block diagram of a motor control device according to one embodiment of the present invention.

A motor control device according to one embodiment of the present invention may comprise a switching unit (100), a first resistor (200), and a control unit (400), and may further include a position measurement sensor (500), amplifiers (610 to 630), a gate driver, and the like.

The switching unit (100) may include a first switch unit (110) and a second switch unit (120). The first switch unit (110) and the second switch unit (120) may each include a plurality of unit switches. The unit switches may include semiconductor switching elements such as FETs, MOSFETs, or IGBTs. It is appreciated that other switching elements may be included. The switching unit (100) may receive a power input and apply a driving power to a motor (300). The switching unit (100) may apply the driving power to control the motor (300) in accordance with the operation of the switching unit (100). When power is applied to the switching unit (100), the driving power is applied to the motor (300) and outputted to an output of the switching unit (100).

A first resistor (200) may be connected to the output of the switching unit (100). The power applied to the switching unit (100) may be applied to the first switch unit (110) and applied to the motor (300), and may also be outputted to the second switch unit (120). A first resistor (200) may be connected to an output of the second switch unit (120) to determine whether the switching unit (100) is operating.

The control unit (400) may control the motor (300) that is connected to the switching unit (100). The control unit (400) may control the motor (300) by starting the motor (300), or by generating a control signal to drive the motor (300) according to a direction, speed, or mode to be controlled when driving the motor (300). The control unit (400) may control the motor (300) by controlling the operation of the switching unit (100) that applies a driving power to the motor (300). The motor (300) can be controlled by controlling the operation of the switching unit (100), that is, controlling the ON-OFF of the unit switches included in the switching unit (100). The control unit (400) may control the duty of the unit switches. Here, the duty is the time the switch stays on for one cycle, which can be used to control the motor (300) by controlling the time that the driving power is delivered to the motor (300) in a switching operation in which the motor (300) is energized.

The control unit (400) may generate a control signal depending on the type of motor (300) to be controlled or the state of the motor (300), including the driving direction of the motor (300).

In order for the control unit (400) to control the motor (300), it is necessary for the control unit (400) to accurately determine the type or state of the motor (300) and perform the control according to the motor (300). By controlling the motor (300) according to the type or state of the motor (300), the motor (300) can be controlled accurately and unnecessary power consumption can be reduced.

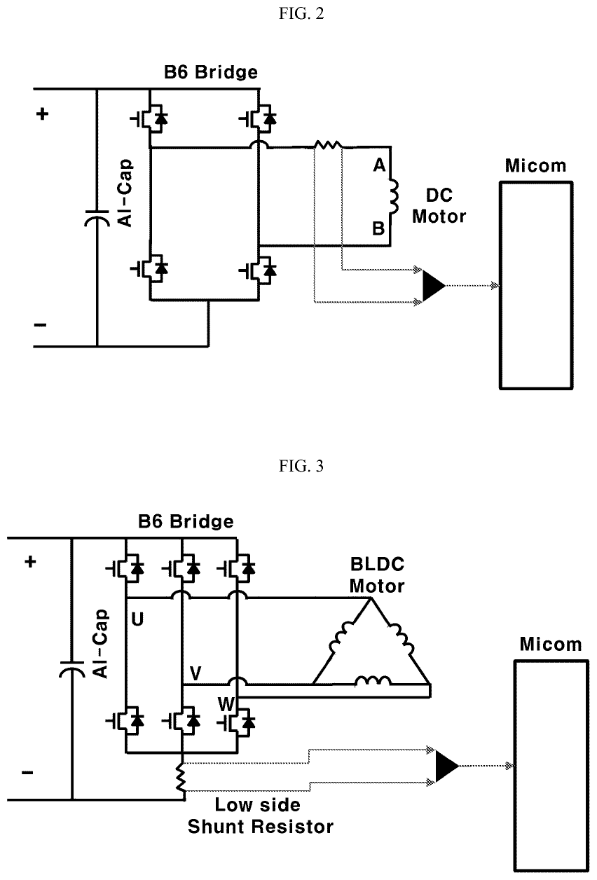

FIGS. 2 and 3 are comparative examples of the present invention, in which a current is measured to determine a state of the motor. As shown in FIG. 2, in a controller (micom) controlling a DC motor, to measure the current of the DC motor, a shunt resistor for measuring the current is placed in the phase output pattern, and the current is detected by the potential difference of the shunt resistor. In order to measure the current of the DC motor at the phase output, a shunt resistor is placed at a phase output unit. Depending on the product to which the DC motor is applied, the direction of rotation can affect the performance of the product, so it is necessary to detect the direction of rotation. In addition, reverse rotation of the rotation direction is required to improve responsiveness, so detection of directionality is important.

The direction of rotation can be determined by detecting a current through a shunt resistor and detecting polarity changes for forward and reverse rotation. Since the current flowing through the shunt resistor is different when the DC motor is in forward or reverse rotation, the potential difference across the shunt resistor is reversed, and the direction of rotation of the motor can be detected.

As shown in FIG. 3, the controller (micom) controlling the BLDC motor places a shunt resistor at the bottom of an output unit to measure the current of the BLDC motor. For cost optimization, one shunt resistor can be applied at the bottom of the output unit to detect the motor current. BLDC motors are basically equipped with a rotor position sensor to detect the rotation of the rotor, so detection of the direction of rotation using current is not necessary.

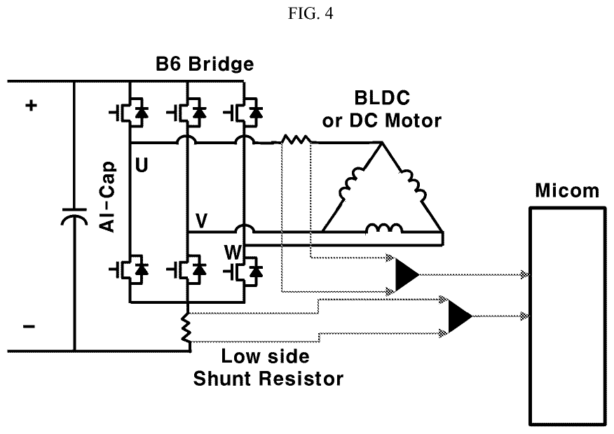

The controller that controls each DC motor and BLDC can use the controller structure of FIG. 2 or FIG. 3, but it is difficult to use the controller structure of FIG. 2 or FIG. 3 to control both DC motor and BLDC. To control both a DC motor and a BLDC motor, the controller can be configured as shown in FIG. 4. The configuration of FIG. 4 can be used to control both a DC motor and a BLDC motor. The motor control device according to FIG. 4 may place a shunt resistor at a phase output unit, as shown in FIG. 2, and apply a shunt resistor to each non-phase output unit for 6-step operation of the BLDC motor. In this way, two shunt resistors can be used to drive a DC motor and a BLDC motor.

However, since the shunt resistor is placed at the phase output unit, an imbalance in the phase resistance of the BLDC motor may occur, resulting in a phase current imbalance when the BLDC motor is driven, which may cause noise due to torque ripple, etc. and adversely affect performance. To solve these problems, adding shunt resistors to each phase may increase the cost and size of the controller. Even if a current sensor is substituted, more than one application is required, and the cost of the components may be high, making the cost uncompetitive. In addition, only the motor needs to be modified outside the controller to drive it, but since DC motors do not have rotor position sensors, an additional method of using a current for direction detection may be required.

Unlike the motor control apparatus for DC motors and BLDC shown in FIG. 4, the motor control device according to an embodiment of the present invention does not dispose a shunt resistor at the phase output unit, but uses the current of a unit switch included in the second switch unit (120).

The second switch unit (120) may include a plurality of unit switches, and the control unit (400) may control the motor (300) by determining the type of the motor (300) or the state of the motor (300) using a switch of at least one of the plurality of unit switches and a current of the first resistor. The control unit (400) may determine the type of the motor (300) or the state of the motor (300) by using the first resistor (200) and the current of the unit switch of at least one of the plurality of unit switches included in the second switch unit (120), and control the motor (300) accordingly. The first resistor (200) is connected to an output unit of the switching unit (100), and when a current flows through the first resistor (200), it can be known that power is applied to the switching unit (100), and accordingly, the power is applied to the motor (300) connected to the switching unit (100). At this time, the motor (300) is driven in accordance with the operation of the switching unit (100), and when the motor (300) is driven, the current flows through one of the unit switches of the second switch unit (120), and the control unit (400) can determine the type or state of the motor (300) by using the current of the unit switch through which the current flows through one of the unit switches of the second switch unit (120).

The motor (300) may include at least one of a DC motor and a BLDC motor. The motor (300) may include a DC motor or a plurality of DC motors, a BLDC motor or a plurality of BLDC motors, or may include at least one DC motor and at least one BLDC motor. The motor (300) may include a variety of motors depending on the number and type of motors required for the device being driven using the motor (300).

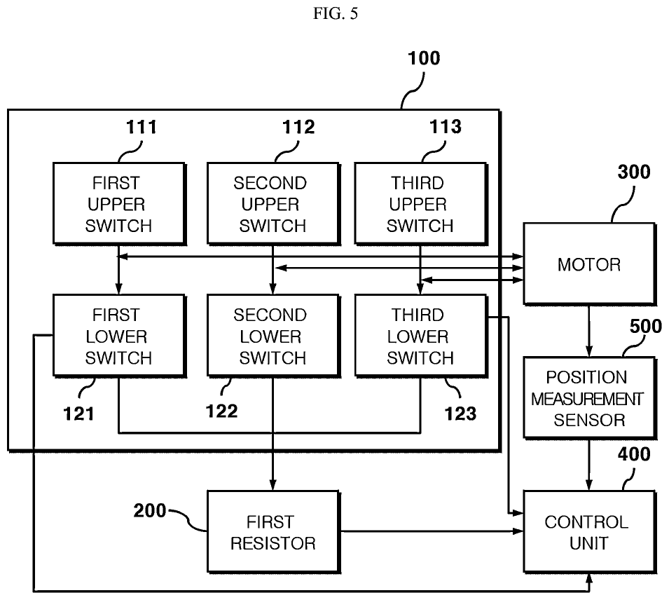

The switching unit (100) may include first to third upper switches (111 to 113) and first to third lower switches (121 to 123) connected in series with the upper switches (111 to 113), respectively. The upper and lower switches connected in series may be complementarily conducted. As shown in FIG. 5, the node between the upper and lower switches connected in series may be connected to the motor (300), and a driving power may be inputted to the motor (300) in response to the ON-OFF operation of the switches. A first resistor (200) may be connected to the output unit of the first to third lower switches (121 to 123). The switching unit (100) may be implemented as a B6 bridge circuit comprising three upper switches and three lower switches.

The control unit (400) can detect the type of motor by turning on the second upper switch (112), the first lower switch (121), and the third lower switch (123), and using a first current flowing in the first lower switch (121), a second current flowing in the third lower switch (123), and a third current flowing in the first resistor (200) to detect the type of motor (300) connected to the switching unit (100). To detect the type of motor (300) connected to the switching unit (100), the control unit (400) may turn on the second upper switch (112), the first lower switch (121), and the third lower switch (123), wherein the current flowing in the first lower switch (121), the third lower switch 123, and the first resistor 200 can be used. To prevent an imbalance of the phase resistors when connecting a BLDC motor, the current flowing in two of the three lower switches, the first lower switch (121) and the third lower switch (123), can be utilized without disposing a shunt resistor in the phase output unit, as shown in FIG. 4. Turning on the second upper switch (112), the first lower switch (121), and the third lower switch (123) may or may not form a path for current to flow, depending on the type of motor (300) to which it is connected.

The control unit (400) may determine that the motor (300) is a BLDC motor (300) if the first current, the second current, and the third current are above a threshold value. In the case of the BLDC motor (300), the first to third upper switches (111 to 113) and the first to third lower switches are all connected, and a path for current to flow from the second upper switch to the motor to the first lower switch and the third lower switch is formed. Therefore, if the first current, the second current, and the third current are above the threshold value, the BLDC motor (300) can be judged to have formed the path when the BLDC motor (300) is connected, and the motor (300) can be judged to be a BLDC motor. Here, the threshold value may be set using a minimum current flowable when a BLDC motor is normally connected, or may be preset by a user.

The first current, the second current, and the third current may be measured using voltage differences across the first lower switch (121), the third lower switch (123), and the first resistor (200). The control unit may include a first amplifier (610) to sense the voltage difference across the two ends of the first lower switch (121), a second amplifier (620) to sense the voltage difference across the two ends of the third lower switch (123), and a third amplifier (630) to sense the voltage difference across the two ends of the first resistor (200). The first lower switch (121) and the third lower switch (123) can measure a current from the voltage at both ends using a resistor inside the switch, and the first resistor (200) can measure a current from the voltage at both ends using its own resistance. The size of the resistor inside the switch is quite small as the resistance between the drain and source in the case of a MOSFET, and the first resistor (200) also uses a resistor with a small resistance value to reduce power loss. For example, the first resistor may be 2 mΩ, and the internal resistance of the first lower switch (121) and the third lower switch (123) may be 3 mΩ. Thus, the magnitude of the voltage at each end is fairly small and may be inputted to the control unit (400) via the first to third amplifiers (610 to 630) to amplify it to a value suitable for the control unit (400) to measure the current. The shunt resistor tolerance of the first resistor may be ±1%, and the motor current measurement may be based on the value measured across the shunt resistor. Here, the first to third amplifiers (610 to 630) may be OP-amps, and may be included in a gate driver.

The third current which is a current of the first resistor (200) may be calculated by the following manner.

$$[ mathematical equation 1 ]$$

$$\begin{matrix}{V}_{LSR} = {I}_{MOT} \times {R}_{shunt} \\ {I}_{MOT} = {V}_{LSR} / {R}_{shunt}\end{matrix}$$

Here, V_LSR is a voltage across the first resistor, R_shunt is a resistor value of first resistor and I_MOT is a third current.

The first current which is a current of first lower switch (121) may be calculated by the following manner.

$$[ mathematical equation 2 ]$$

$$\begin{matrix}{V}_{L 1} = {I}_{MOT} \times {R}_{ds\_L 1} \\ {I}_{MOT\_L 1} = {V}_{L 1} / {R}_{ds\_L 1}\end{matrix}$$

Here, V_L1 is a voltage across the first lower switch (121), R_ds_L1 is an internal resistance value of first lower switch (121), and I_MOT_L1 is a first current.

The second current which is a current of third lower switch (123) may be calculated by the following manner.

$$[ mathematical equation 3 ]$$

$$\begin{matrix}{V}_{L 3} = {I}_{MOT} \times {R}_{ds\_L 3} \\ {I}_{MOT\_L 3} = {V}_{L 3} / {R}_{ds\_L 3}\end{matrix}$$

Here, V_L3 is a voltage across the third lower switch (123), R_ds_L3 is an internal resistance value of third lower switch (123), and I_MOT_L3 is a second current.

The control unit (400) may not immediately determine that the motor (300) is a BLDC motor based on the first current, second current, and third current being above a threshold, but may make a more accurate determination using position measurement values received from a position measurement sensor (500) that measures the position of the motor (300). The BLDC motor may include a position measurement sensor (500) that measures the position of a rotor of the BLDC motor, and the position measurement value from the position measurement sensor (500) may be used to drive the BLDC motor. Here, the position measurement sensor may be a Hall sensor that measures the position of the motor (300). For position measurement of a three-phase BLDC motor, three Hall sensors may be disposed with a 120 degree phase difference to measure the position of the motor (300). In addition to Hall sensors, various other position measurement sensors may be applied.

When the first current, the second current, and the third current flow above a threshold, the motor (300) is running, and the position of the motor (300) changes, thereby causing a position measurement value to be outputted from the position measurement sensor (500). In this case, it can be determined that the current input to the BLDC motor is flowing normally and that the BLDC motor is operating normally, and the control unit (400) can determine that the motor (300) is a BLDC motor when the first current, the second current, and the third current are above the threshold value and the position measurement value is in the normal range.

If the position measurement value is outside the normal range even though the first current, second current, and third current are above the threshold value, it may be determined that the position measurement sensor has failed or that the BLDC motor is not running normally. If the first current, second current, and third current are detected normally, the power application of the drive power to the BLDC motor is operating normally, and it can be determined that the position measurement sensor has malfunctioned. Here, the normal range of the position measurement value may be set by obtaining the position measurement value output by the position measurement sensor in normal operation through experimentation, or may be set by the user. Alternatively, it may be determined that the BLDC motor is not running normally.

Since the control unit (400) controls the BLDC motor based on the position measurement value of the position measurement sensor (500), it is difficult to control the motor normally if the position measurement sensor (500) fails. Therefore, if the first current, the second current, and the third current are above a threshold value but the position measurement value is outside the normal range, the control unit (400) may control the motor (300) in a safe mode. In this case, the control unit (400) may stop driving the motor 300.

The control unit (400) may determine that the motor (300) is a DC motor if the first current, the second current, and the third current do not flow. Unlike the BLDC motor, the DC motor is not connected with all of the first to third upper switches (111 to 113) and the first to third lower switches, but is connected with two upper switches and two lower switches. In this case, the two lower switches may be the first lower switch (121) and the third lower switch (123), which measure the first current and the second current. That is, the DC motor is connected with the first upper switch (111), the third upper switch (113), the first lower switch (121), and the third lower switch (123), such that when the second upper switch (112), the first lower switch (121), and the third lower switch (123) are turned on, a path from the second upper switch (112) to the motor to the first lower switch (121) or from the second upper switch (112) to the motor to the third lower switch (123) is not formed. Since no current is formed, no current flows through the switching unit (100). Taking advantage of this, when the first current, the second current, and the third current do not flow, the control unit (400) can determine that the motor (300) is a DC motor. The motor (300) may also be determined to be a DC motor if at least one of the first current, the second current, and the third current is measured below a preset current value in consideration of a case where a small current flows due to noise or the like rather than a flow of current due to a normal current path.

The control unit (400) may not immediately determine that the motor (300) is a DC motor based on the first current, the second current, and the third current being below a threshold or not flowing, but may make a more accurate determination using a position measurement value received from the position measurement sensor (500) that measures the position of the motor (300). Since a DC motor, unlike a BLDC motor, does not output a position measurement value by the position measurement sensor (500), the control unit (400) may determine that the motor (300) is a DC motor if the position measurement value received from the position measurement sensor (500) that measures the position of the motor (300) is less than or equal to the first value.

The control unit (400) may determine that the motor (300) is a DC motor if at least one of the first current, the second current, and the third current is below a threshold value, but at least one of the first current, the second current, and the third current flows, or if the position measurement value received from the position measurement sensor (500) is greater than the first value. In the case where at least one of the first current, the second current, and the third current is below the threshold value, but at least one of the first current, the second current, and the third current flows, an abnormal current path is formed and at least one current flows even when the BLDC motor is connected and operating normally, and in this case, it can be determined that the power is abnormal. It can be judged as an abnormality of the power source or the switching unit (100).

Furthermore, even if the BLDC motor is connected and operates normally when at least one of the first current, the second current, and the third current is less than the threshold, if the position measurement value received from the position measurement sensor is greater than the first value, the BLDC motor may be connected and operated, and in this case, it may be judged to be overpowered.

The control unit (400) may determine the direction of rotation (rotation direction) of the motor (300) using the first current, the second current, and the third current. When a BLDC motor is connected, the control unit (400) may determine the direction of rotation using the position measurement value of the position measurement sensor (500). However, when a DC motor is connected, it is difficult to determine the direction of rotation using the position measurement value, so the control unit (400) may determine the direction of rotation of the DC motor using at least one of the first current and the second current together with the third current to determine the direction of rotation of the motor. The control unit (400) may determine the direction of rotation of the motor by using at least one of the first current and the second current together with the third current when the motor (300) is determined to be a DC motor as a result of receiving information that the DC motor is connected, or by turning on the second upper switch (112), the first lower switch (121), and the third lower switch (123).

To determine the direction of rotation of the motor, the control unit (400) may turn on the first upper switch (111) and the third lower switch (123), and determine that the DC motor rotates in the first direction if the third current and the second current remain above a threshold value for a threshold time. As described above, the DC motor is connected with the first upper switch (111), the third upper switch (113), the first lower switch (121), and the third lower switch (123). One end of the motor (300) is connected to the node between the first upper switch (111) and the first lower switch (121), and the other end of the motor (300) is connected to the node between the third upper switch (113) and the third lower switch (123).

At this time, when the first upper switch (111) and the third lower switch (123) are turned on, a path is formed from the first upper switch (111)-the motor-the third lower switch (123). The control unit (400) can determine the direction of rotation by turning on the first upper switch (111) and the third lower switch (123) and determining whether the current flows normally. If the third current, which is the current flowing in the first resistor (200), remains above a threshold value for a threshold time or longer, the current path of the switching unit (100) is normally connected and outputted to an output unit, and it can be determined that the switching unit (100) is operating normally. In addition, if the second current, which is the current flowing in the third lower switch (123), is maintained above a threshold value for a threshold time or longer, the third lower switch is connected to the other end of the motor, and it can be determined that the DC motor rotates in a first direction. Here, the first direction may be the direction in which the motor (300) rotates when current is inputted to the one end and current is outputted to the other end.

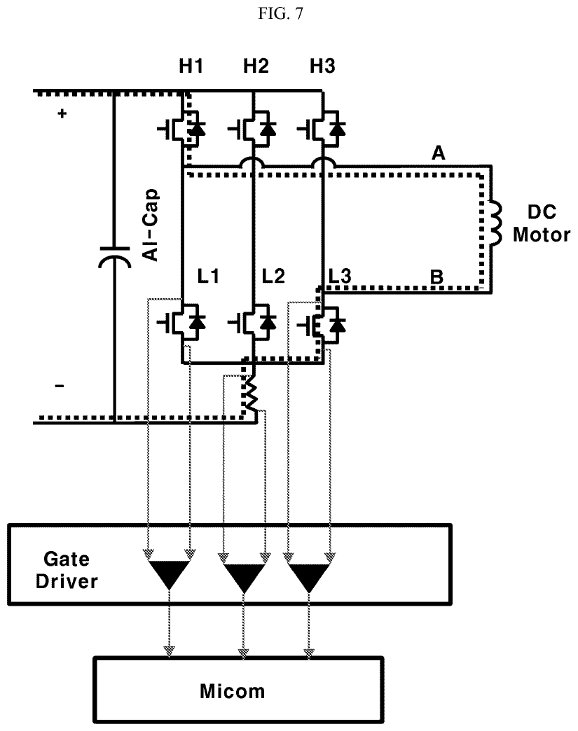

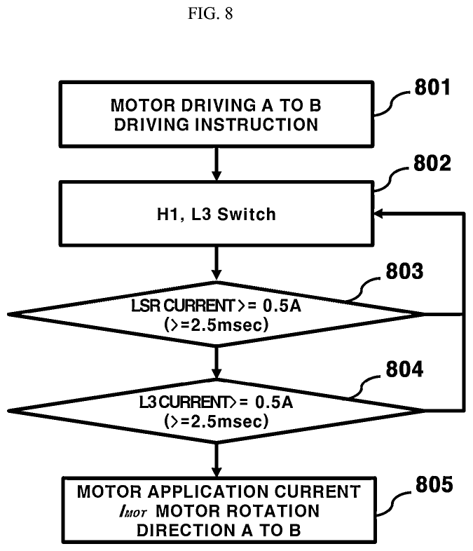

If the motor (300) is a DC motor, and the first upper switch (111) and the third lower switch (123) are turned on, a current may flow as shown in FIG. 7. One end (A) of the DC motor is connected to a node between the first upper switch (H1) and the first lower switch (L1), and the other end (B) of the motor is connected to a node between the third upper switch (H3) and the third lower switch (L3). At this time, as shown in FIG. 8, a control signal (801), which is an instruction to drive the motor in the direction from A to B, may be outputted to determine the rotation direction of the motor. According to the control signal, the first upper switch (H1) and the third lower switch (L3) are turned on (802), and a path is formed from the first upper switch (H1)-one end of the motor (A)-the other end of the motor (B)-the third lower switch (L3). At this time, if the third current (LSR), which is the current flowing in the first resistor (200), maintains a threshold value of 0.5 A or more for a threshold time of 2.5 msec or more (803), and the second current (L3 current), which is the current flowing in the third lower switch (123), maintains a threshold value of 0.5 A or more for a threshold time of 2.5 msec or more (804), it can be determined (805) that the DC motor rotates from the A to B direction.

In the case of turning on the third upper switch (113) and the first lower switch (121), a path is formed from the third upper switch (113)-motor-first lower switch (121).

When the third upper switch (113) and the first lower switch (121) are turned on, a path is formed from the third upper switch (113)-the motor-the first lower switch (121). The control unit (400) can determine the direction of rotation by turning on the third upper switch (113) and the first lower switch (121) and determining whether the current flows normally. If the third current, which is the current flowing in the first resistor (200), remains above a threshold value for a threshold time or longer, the current path of the switching unit (100) is normally connected and outputted to the output unit, and it can be determined that the switching unit (100) is operating normally. In addition, if the first current, which is the current flowing in the first lower switch (121), is maintained above the threshold value for more than a threshold time, the first lower switch is connected to the one end of the motor, and it can be determined that the DC motor rotates in a second direction. Here, the second direction is the direction in which the motor (300) rotates when current is inputted to the other end and current is outputted to the one end, which may be the opposite direction from the first direction.

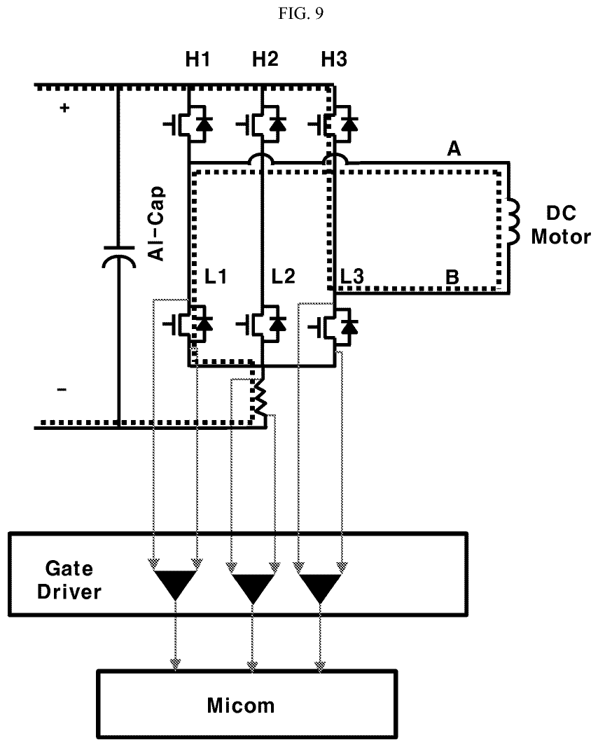

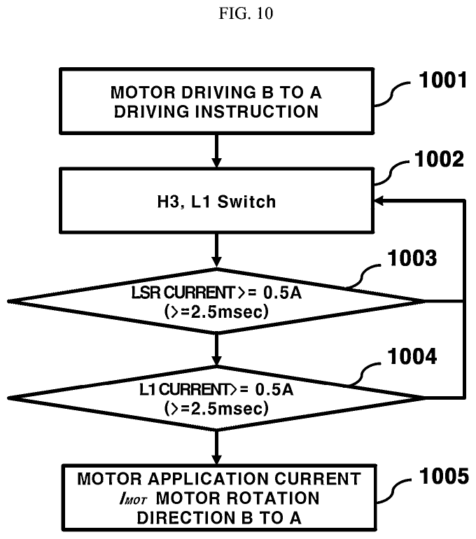

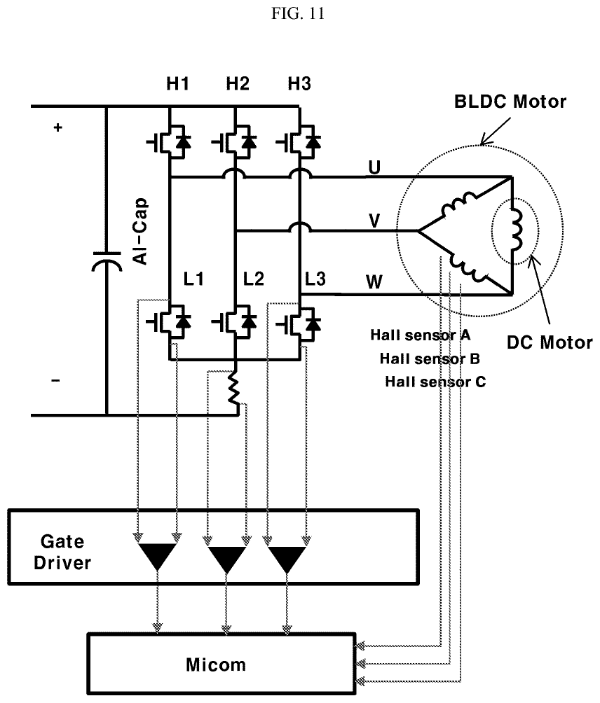

If the motor (300) is a DC motor, and the third upper switch (113) and the first lower switch (121) are turned on, current may flow as shown in FIG. 9. One end (A) of the DC motor is connected to the node between the third upper switch (H3) and the third lower switch (L3), and the other end (B) of the motor is connected to the node between the first upper switch (H1) and the first lower switch (L1). At this time, as shown in FIG. 10, a control signal (1001), which is an instruction to drive the motor from B to A, may be outputted to determine the direction of rotation of the motor. According to the control signal, the third upper switch (H3) and the first lower switch (L1) are turned on (1002), and a path is formed from the third upper switch (H3)-the other end (B) of the motor-the one end (A) of the motor-the first lower switch (L1). At this time, if the third current (LSR), which is a current flowing in the first resistor (200), maintains a threshold value of 0.5 A or more for a threshold time of 2.5 msec or more (1003), and the second current (L1 current), which is a current flowing in the first lower switch (121), maintains a threshold value of 0.5 A or more for a threshold time of 2.5 msec or more (1005), it can be determined that the DC motor rotates from B to A (1006).

As described above, if the motor (300) is a DC motor as a result of determining the type of the motor (300) and whether the motor (300) is in normal operation, the control unit (400) may control the DC motor by complementarily conducting (energizing) the first upper switch (111) and the third upper switch (113) and the first lower switch (121) and the third lower switch (123) after determining the direction of rotation of the motor (300).

If it is desired to rotate the DC motor in the first direction (A to B) or to stop the DC motor rotating in the second direction, the control unit (400) may turn on the first upper switch (111) and the third lower switch (123) and turn off the third upper switch (113) and the first lower switch (121). If it is desired to rotate the DC motor in the second direction (B to A) or to stop the DC motor rotating in the first direction, the control unit (400) may turn on the third upper switch (113) and the first lower switch (121) and turn off the first upper switch (111) and the third lower switch (123).

If the motor (300) is a BLDC motor, the control unit (400) may control the BLDC motor by complementarily conducting (energizing) the first to third upper switches (111 to 113) and the first to third lower switches (121 to 123). They can be turned on in a first-second-third order with a phase difference, or in a first-third-second order with a phase difference to rotate in a first direction or a second direction.

A motor control device for both a DC motor and a BLDC motor according to an embodiment of the present invention may be implemented as shown in FIG. 11. The switching unit may comprise first to third upper switches (H1, H2, H3) and first to third lower switches (L1, L2, L3), which may be connected to a motor by forming a B6 bridge. The motor may be a DC motor or a BLDC motor. When connected to a BLDC motor, all three patterns of U, V, and W are connected, and when connected to a DC motor, only U (A) and W (B) patterns are connected. A capacitor (Al-cap) may be connected to an input end of the switching unit. The switching unit can receive input the power from a power supply part and transmit it to the motor. In this case, the power source may be a battery or an external power source. A first resistor may be connected to the output unit of the switching unit. The control unit (micom) may determine the type or state of the motor using the current flowing in the first lower switch (L1), the third lower switch (L3), and the first resistor. For this purpose, the voltage difference between the two ends of the first lower switch (L1), the third lower switch (L3), and the first resistor is measured using an amplifier included in the gate driver, and the result is inputted to the control unit (400) to measure the first current or the third current. Using the first and third currents and the position measurement values of the Hall sensors (A, B, and C), which are position measurement sensors that measure the position of the motor, the type and state of the motor can be determined.

By implementing a motor control unit as described above, it is possible to configure a controller for both DC and BLDC motors. In addition, a platform controller with an optimized shunt resistance can be implemented, and it is possible to distinguish options and control the operation of each type of motor without distinguishing hard air. Furthermore, it is possible to detect the current and direction of the DC motor without interfering with the operation of the BLDC motor.

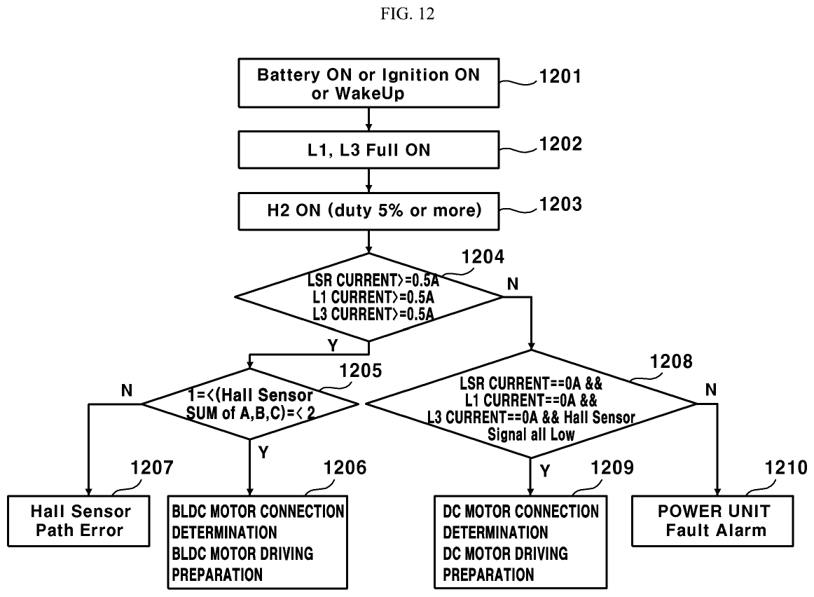

The motor driving method according to an embodiment of the present invention can determine and control a type of motor by using a switch of at least one of a plurality of unit switches connected to the motor and a current of a first resistor connected to an output end of the plurality of unit switches. The detailed description of the motor driving method according to an embodiment of the present invention corresponds to the detailed description of the motor driving device described above, and the redundant description will be omitted hereinafter. The motor driving method according to an embodiment of the present invention can determine a type or state of a motor, as shown in FIG. 12.

When the battery or ignition is switched on, or when operating in wake-up mode (1201), the first lower switch (L1) and the third lower switch (L3) are first switched on (1202) and the second upper switch (H2) is switched on (1203). At this time, the first lower switch (L1) and the third lower switch (L3) are made to be always full on, and the second upper switch (H2) can be turned on at a duty of 5% or more.

At this time, it is determined (1204) whether the current flowing in the first resistor (LSR), the L1 current, and the L3 current are above a threshold of 0.5 A. If the LSR, L1 current, and L3 current are above the threshold, it is determined (1205) that the sum of the position measurement values of the Hall sensors (A, B, and C), which are position measurement sensors that measure the position of the motor, is greater than or equal to 1 and less than or equal to 2. If the sum of the position measurement values of the Hall sensors (A, B, and C) is greater than or equal to 1 and less than or equal to 2, it is determined that the BLDC motor is connected, and preparations for driving the BLDC motor are performed (1206). If the sum of the position measurement values of Hall sensors (A, B, and C) is less than 1 or more than 2, it is determined (1207) that an error has occurred in the output path of the Hall sensor.

If at least one of the LSR, the L1 current, and the L3 current is below the threshold value, the LSR, the L1 current, and the L3 current do not flow and the output of the Hall sensor (A, B, C) is determined if the output of the Hall sensor (A, B, C) is low(1208). If the LSR, the L1 current, and the L3 current do not flow and the output of Hall sensor (A, B, C) is low, it is determined that a DC motor is connected, and preparation for driving the DC motor is performed (1209). If at least one of the LSR, the L1 current, and the L3 current flows or the output of the Hall sensor (A, B, C) is high, it is determined that a malfunction has occurred in the power section and an alarm is generated (1210).

In detecting the type of motor through the above process, the type of motor can be detected and the corresponding motor driving environment can be applied without physical changes to the motor control device.

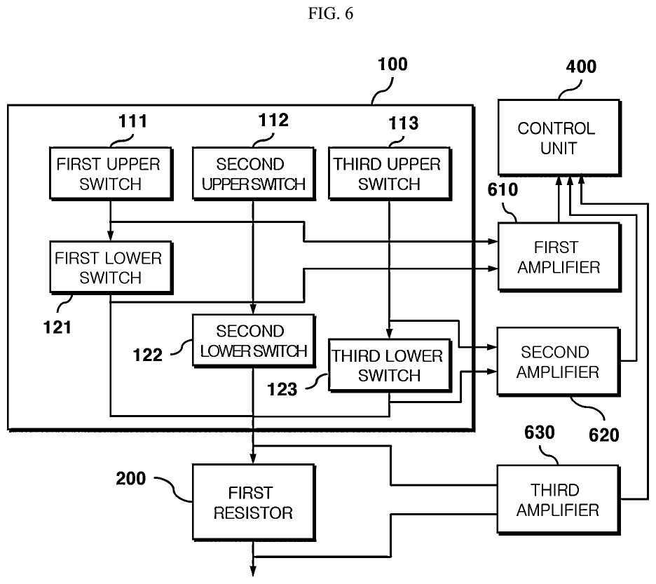

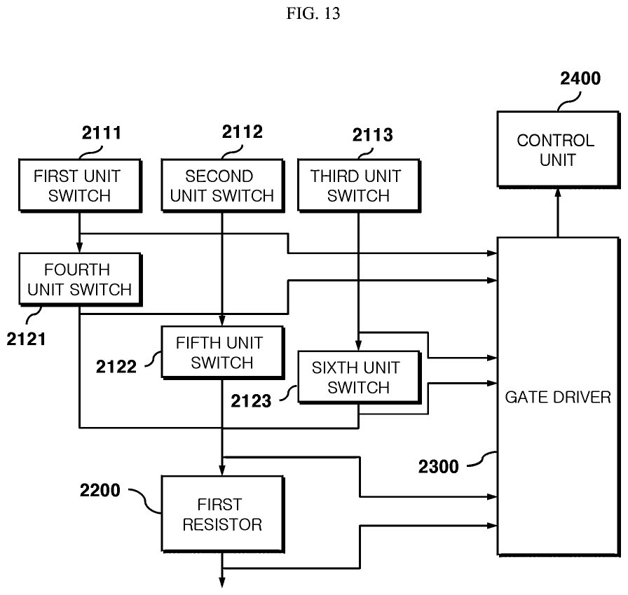

A motor control device according to an embodiment of the present invention comprises a first to sixth unit switch, a first resistor, a gate driver, and a control section, and may be implemented as shown in FIG. 13. The detailed description of the motor control device according to an embodiment in FIG. 13 corresponds to the detailed descriptions of the motor control device and motor control method in FIGS. 1 to 12, and redundant descriptions will be omitted hereinafter.

A motor control device according to an embodiment of the present invention may include first to third unit switches (2111 to 2113), fourth to sixth unit switches (2114 to 2116) connected in series with the first to third unit switches (2111 to 2113) respectively, a first resistor (2200) connected with output ends of the fourth to sixth unit switches (2114 to 2116), a gate driver (2300) in connection with both ends of the fourth unit switch (2114), both ends of the sixth unit switch (2116), and a control unit (2400) in connection with the gate driver (2300), with both ends of the first resistor (2200) in connection with the gate driver (2300).

The control unit (2400) may control a first DC motor or a second DC motor associated with the unit switches of at least some of the first to sixth unit switches (2111 to 2116), wherein the first DC motor may be a DC motor or a single-phase motor, and the second DC motor may be a BLDC motor or a three-phase motor.

Meantime, embodiments of the present invention can be implemented as computer-readable code on a computer-readable recording medium. A computer-readable recording medium includes any kind of recording device that stores data that can be read by a computer system.

Examples of computer-readable recording media include ROM, RAM, CD-ROM, magnetic tape, floppy disk, optical data storage, and the like. Furthermore, the computer-readable recording media may be distributed across networked computer systems, such that the computer-readable code may be stored and executed in a distributed manner. Furthermore, functional programs, code, and code segments for implementing the present invention can be readily deduced by programmers of ordinary skill in the art to which the present invention belongs.

One of ordinary skill in the art to which the present invention relates will understand that the invention may be implemented in modified form without departing from the essential features of the above description. The disclosed methods are therefore to be considered from an illustrative and not a limiting point of view. The scope of the invention is shown in the claims of the patent and not in the foregoing description, and all differences within the scope of the claims are to be construed as being included in the invention.

1. A motor control device, comprising:
a switching unit comprising a first switch unit and a second switch unit;
a first resistor connected to an output unit of the switching unit; and
a control unit configured to control a motor connected with the switching unit,
wherein the second switch unit comprises a plurality of unit switches, and
wherein the control unit determines a type of the motor by using at least one switch from among the plurality of unit switches and a current flowing through the first resistor.

2. The motor control device of claim 1, wherein the motor comprises at least one of a DC motor and a BLDC motor.

3. The motor control device of claim 1, wherein the switching unit comprises: first to third upper switches; and first to third lower switches, each connected in series with a respective upper switch;
wherein the control unit turns on the second upper switch, the first lower switch, and the third lower switch, and detects the type of the motor using a first current flowing in the first lower switch, a second current flowing in the third lower switch, and a third current flowing in the first resistor.

4. The motor control device of claim 3, wherein the control unit determines that the motor is a BLDC motor if, when the first current, the second current, and the third current are above a threshold value, a position measurement value received from a position measurement sensor that measures a position of the motor is within a normal range.

5. The motor control device of claim 4, wherein the control unit determines that the position measurement sensor is defective if the position measurement value is out of the normal range.

6. The motor control device of claim 3, wherein the control unit determines that the motor is a DC motor if the first current, the second current, and the third current do not flow, and a position measurement value received from the position measurement sensor that measures the position of the motor is below a first value.

7. The motor control device of claim 6, wherein the control unit determines as a power fault if at least one of the first current, the second current, and the third current is below a threshold value, but at least one of the first current, the second current, and the third current flows, and the position measurement value received from the position measurement sensor is greater than the first value.

8. The motor control device of claim 6, wherein the control unit determines that the DC motor rotates in a first direction when the first upper switch and the third lower switch are turned on, and the third current and the second current remain above a threshold value for a threshold time, and determines that the DC motor rotates in a second direction when the third upper switch and the first lower switch are turned on, and the third current and the first current remain above a threshold value for a threshold time.

9. The motor control device of claim 3, comprising:
a first amplifier configured to detect a voltage difference across both sides of the first lower switch;
a second amplifier configured to detect a voltage difference across both sides of the third lower switch; and
a third amplifier configured to detect a voltage difference across both sides of the first resistor.

10. The motor control device of claim 3, wherein, if the motor is a DC motor, the control unit controls the DC motor by complementarily energizing the first upper switch, the third upper switch, the first lower switch, and the third lower switch, and, if the motor is a BLDC motor, controls the BLDC motor by complementarily energizing the first upper switch, the third upper switch, the first lower switch, and the third lower switch.

11. A motor control device, comprising:
a first unit switch, a second unit switch, and a third unit switch;
a fourth unit switch, a fifth unit switch, and a sixth unit switch connected in series to each of the first unit switch, the second unit switch, and the third unit switch;
a first resistor connected to output ends of the fourth unit switch, the fifth unit switch, and the sixth unit switch;
a gate driver connected to both ends of the fourth unit switch and both ends of the sixth unit switch; and
a control unit connected with the gate driver,
wherein both ends of the first resistor are connected to the gate driver.

12. The motor control device of claim 11, wherein the control unit controls a first DC motor or a second DC motor connected to at least some unit switches of the first unit switch, the second unit switch, the third unit switch, the fourth unit switch, the fifth unit switch, and the sixth unit switch.

13. The motor control device of claim 12, wherein the first DC motor is a DC motor or a single-phase motor, and the second DC motor is a BLDC motor or a three-phase motor.

14. The motor control device of claim 11, wherein the first unit switch, the second unit switch, the third unit switch, the fourth unit switch, the fifth unit switch, and the sixth unit switch are connected to a motor, and
wherein the control unit determines a type of the motor by using at least one switch from among the first unit switch, the second unit switch, the third unit switch, the fourth unit switch, the fifth unit switch, and the sixth unit switch and a current flowing through the first resistor.

15. The motor control device of claim 14, wherein the control unit turns on the second switch, the fourth switch, and the sixth switch, and detects the type of the motor using a first current flowing in the fourth switch, a second current flowing in the sixth switch, and a third current flowing in the first resistor.

16. The motor control device of claim 15, wherein the control unit determines that the motor is a BLDC motor if, when the first current, the second current, and the third current are above a threshold value, a position measurement value received from a position measurement sensor that measures a position of the motor is within a normal range.

17. The motor control device of claim 16, wherein the control unit determines that the position measurement sensor is defective if the position measurement value is out of the normal range.

18. The motor control device of claim 15, wherein the control unit determines that the motor is a DC motor if the first current, the second current, and the third current do not flow, and a position measurement value received from the position measurement sensor that measures the position of the motor is below a first value.

19. The motor control device of claim 18, wherein the control unit determines as a power fault if at least one of the first current, the second current, and the third current is below a threshold value, but at least one of the first current, the second current, and the third current flows, and the position measurement value received from the position measurement sensor is greater than the first value.

20. The motor control device of claim 18, wherein the control unit determines that the DC motor rotates in a first direction when the first switch and the fourth switch are turned on, and the third current and the second current remain above a threshold value for a threshold time, and determines that the DC motor rotates in a second direction when the third switch and the fourth switch are turned on, and the third current and the first current remain above a threshold value for a threshold time.
